(19) United States
(12) Patent Application Publication
(10) Pub. No.: US 2014/0061651 A1
(43) Pub. Date: Mar. 6, 2014

(54) ELECTROPHORETIC DISPLAY DEVICE WITH PHOTO DETECTING INPUT

(71) Applicants: Yang-Hui Chang, Hsinchu County (TW); Naejye Hwang, HSINCHU CITY (TW); Shen-Tai Liaw, Hsinchu City (TW)

(72) Inventors: Yang-Hui Chang, Hsinchu County (TW); Naejye Hwang, HSINCHU CITY (TW); Shen-Tai Liaw, Hsinchu City (TW)

(21) Appl. No.: 13/596,064

(22) Filed: Aug. 28, 2012

(51) Int. Cl. H01L 33/08

(52) U.S. Cl. 257/59; 257/71; 257/E33.053

(57) ABSTRACT

An electrophoretic display device includes a photosensitive transistor in a thin-film-transistor layer that may be used to receive an optical signal as input control signal. The thin-film-transistor layer also includes an electrical switch element for driving an electrophoretic layer to display content. A switching transistor may also be included in the thin-film-transistor layer for selectively turning on the photosensitive transistor. By incorporating the photosensitive transistor and the switching transistor into the existing thin-film-transistor layer of an active matrix electrophoretic display device, optical sensing touch control is made applicable in the electrophoretic display device without compromising its advantageous light, flexible, thin features.

### BACKGROUND OF THE INVENTION

1. Field of the Invention

The invention relates to an electrophoretic display device, and more particularly, to an electrophoretic display device with photo detecting input.

2. Description of the Prior Art

Electrophoretic display device, or electronic paper, has provided display devices with even thinner, lighter, much more flexible features than conventional flat panel displays in recent years. Most electronic paper applications provide simply a reading experience for a user. Generally, an electronic paper device includes an ITO electrode, a pixel electrode, and electrophoretic substance disposed therebetween. The electrophoretic substance contain positively charged particles of one color and negatively charged particles of another color, such that application of an electric field to the ITO electrode and the pixel electrode causes migration of the particles of one color or the other color, depending on the polarity of the field, toward the surface of the electrophoretic substance that shows a perceived color change.

There is, however, an escalating need for a traditional electronic paper device to have touch controllability, either by hands or with stylus. Such touch controllability on the electronic paper device may be realized by using an additional touch panel, including a cover lens and a sensor layer, adding to the electronic paper device. This, however, will extensively increase the cost and the dimension of the electronic paper device, not to mention the generic advantages of the electronic paper device, its thin, light, flexible features, will certainly be compromised.

### SUMMARY OF THE INVENTION

Embodiments of the invention provide an electrophoretic display device. The electrophoretic display device includes a substrate, a thin-film-transistor layer, a sealing layer, an electrophoretic layer, a transparent conductive layer, and a protective layer. The thin-film-transistor layer includes an electrical switch element disposed on the substrate and a photosensitive transistor disposed on the substrate. The photosensitive transistor is capable of detecting an optical signal and converting the optical signal into a current signal. The sealing layer is disposed on the thin-film-transistor layer. The electrophoretic layer is disposed on the sealing layer. The transparent conductive layer is disposed on the electrophoretic layer. The protective layer is disposed on the transparent conductive layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an illustration of an electrophoretic display device according to an embodiment of the invention.

FIG. 2 is an illustration showing sectional structure of a first embodiment of the electrophoretic display device.

FIG. 3 is an illustration showing sectional structure of a second embodiment of the electrophoretic display device.

FIG. 4 is an illustration showing sectional structure of a third embodiment of the electrophoretic display device.

FIG. 5 is an illustration of a first embodiment of an equivalent circuit of a pixel structure of the electrophoretic display device.

FIG. 6 is an illustration of a second embodiment of an equivalent circuit of a pixel structure of the electrophoretic display device.

### DETAILED DESCRIPTION

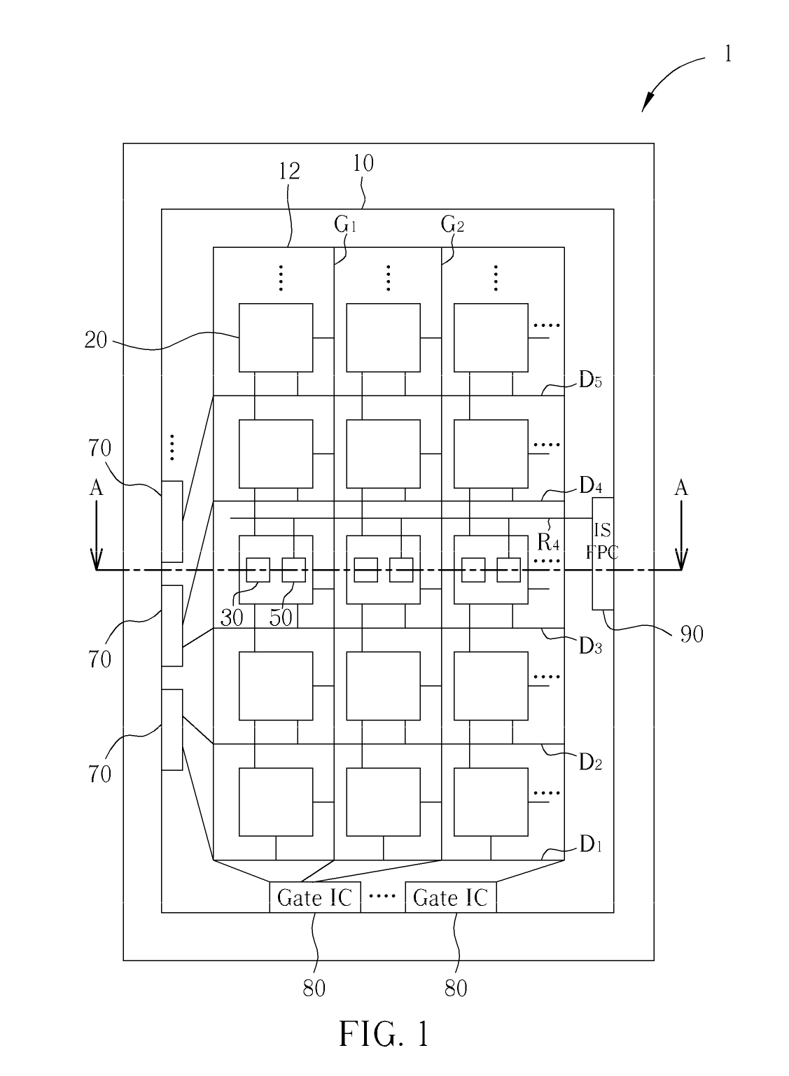

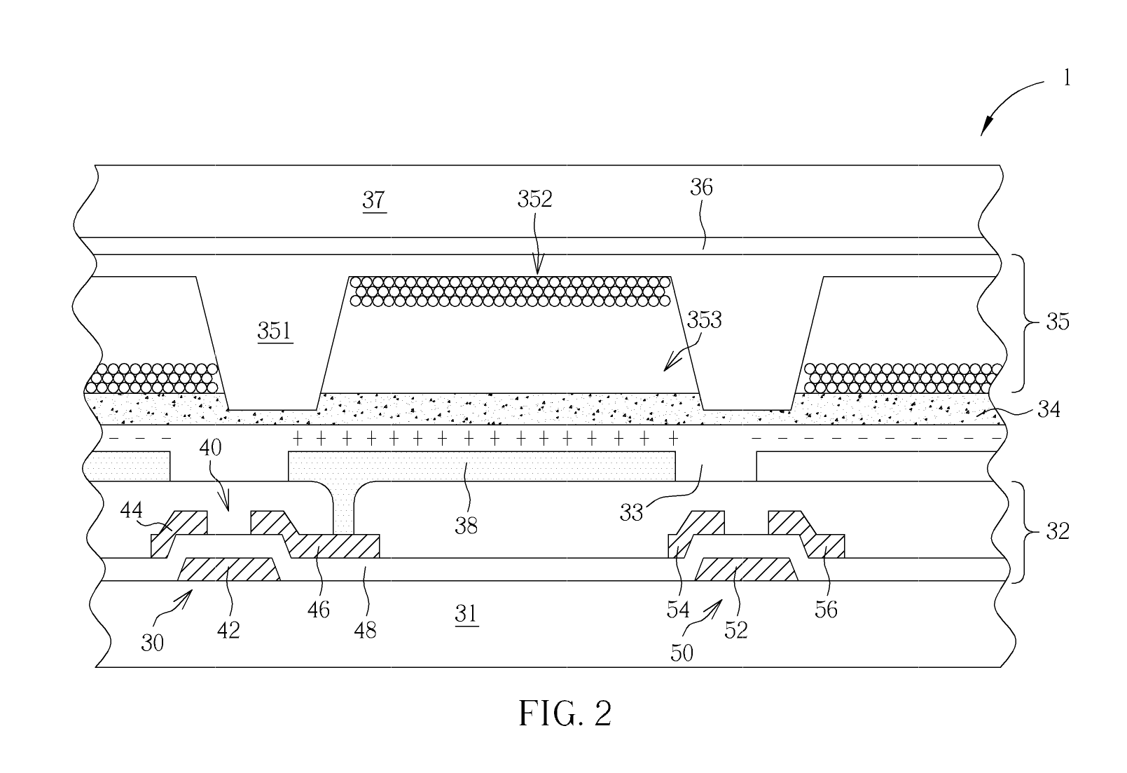

FIG. 1 is an illustration of an electrophoretic display device 1 according to an embodiment of the invention. The electrophoretic display device 1 uses an array glass 10 having an active area 12 composed by a plurality of pixel structures 20 formed in rows and columns. Each pixel structure 20 is disposed near an intersection of one of a plurality of gate lines Gₙ and one of a plurality of data lines Dₙ orthogonal to the gate lines Gₙ, where n represents positive integers. Each of the plurality of gate lines Gₙ is selectively selected by a gate IC 80, and each of the plurality of data lines Dₙ is electrically connected to a source IC 70. Each pixel structure 20 includes an electrical switch element 30, which includes at least a thin film transistor (TFT) 40 as shown in FIG. 2, and at least some of the pixel structures 20 also include a photosensitive transistor 50 as indicated in FIG. 1. The photosensitive transistor 50 may function to detect light and serve as a switch. In the embodiment as shown in FIG. 1, the photosensitive transistors 50 may be implemented in every specific rows of pixel structures 20, say the blue pixel for example. In another embodiment of the invention, the photosensitive transistors 50 may be implemented in a central pixel structure 20 of a matrix composed by a plurality of pixel structures 20. Still in another embodiment of the invention, the photosensitive transistors 50 may be implemented in all pixel structures 20. Referring to FIG. 1, which shows an implementation of the photosensitive transistors 50 in every specific row of pixel structures 20, the photosensitive transistors 20 electrically connect to a read-out line R₄ that is in turn connected to a flexible printed circuit (FPC) 90, which provides the signals generated by the photosensitive transistors 50 for following touch control process.

Please refer to FIG. 2. FIG. 2 is an illustration showing sectional structure of a first embodiment of the electrophoretic display device 1 from the cutting line A-A in FIG. 1. The electrophoretic display device 1 is preferably an active matrix electrophoretic display device and includes a substrate 31, a thin-film-transistor layer 32 disposed on the substrate 31, an adhesive layer 33 covering on the thin-film-transistor layer 32, a sealing layer 34 disposed on the adhesive layer 33, an electrophoretic layer 35 disposed on the sealing layer 34, a transparent conductive layer 36 disposed on the electrophoretic layer 35, and a protective layer 37 disposed on the transparent conductive layer 36. The thin-film-transistor layer 32 includes at least the electrical switch element 30 as shown in FIG. 1, and the photosensitive transistor 50. Both the electrical switch element 30 and the photosensitive transistor 50 are disposed on the substrate 31 and the photosensitive transistor 50 is capable of detecting an optical signal and converting the optical signal into a current signal. The electrical switch element 30 preferably includes a thin film transistor (TFT) 40, which includes a gate 42 disposed on the substrate 31, a gate dielectric layer 48 covering on the gate 42, and a source 44 and a drain 46 disposed on the gate dielectric layer 48. The photosensitive transistor 50 includes a gate 52 disposed on the substrate 31 and covered by the gate dielectric layer 48, and a source 54 and a drain 56 disposed on the gate dielectric layer 48. The drain 46 of the thin film transistor 40 is further coupled to a pixel electrode 38.

The adhesive layer 33 has a smooth top surface where the sealing layer 34 and the electrophoretic layer 35 are disposed. The electrophoretic layer 35 preferably includes a microcup structure 351 that has a plurality of microcups 352 and dielectric fluid 353 filled in each of the plurality of microcups 352. The dielectric fluid 353 contains positively charged particles of one color and negatively charged particles of another color, such that application of an electric field to an ITO electrode in the transparent conductive layer 36 and the pixel electrode 38 causes migration of the particles of one color or the other color, depending on the polarity of the field, toward the surface of the electrophoretic layer 35 that shows a perceived color change. The sealing layer 34 seals the dielectric fluid 353 in each independent microcup 352, preventing the particles in the dielectric fluid 353 from randomly migrating to any part of the device.

The transparent conductive layer 36 serves as a common voltage of the electrophoretic display device 1 and the protective layer 37 is preferably made up with polyester (PET) such as a transparent plastic substrate.

As previously mentioned, the electrophoretic display device 1 in the embodiment of the invention is preferably an active matrix electrophoretic display device, where the pixel electrode 38 and the transparent conductive layer 36 are utilized as a bottom electrode and a top electrode of the electrophoretic layer 35. When the gate 42 is selected such that the thin film transistor 40 is turned on, a vertical electrical field is provided by the pixel electrode 38 that is used to control the position of the charged particles in the dielectric fluid 353.

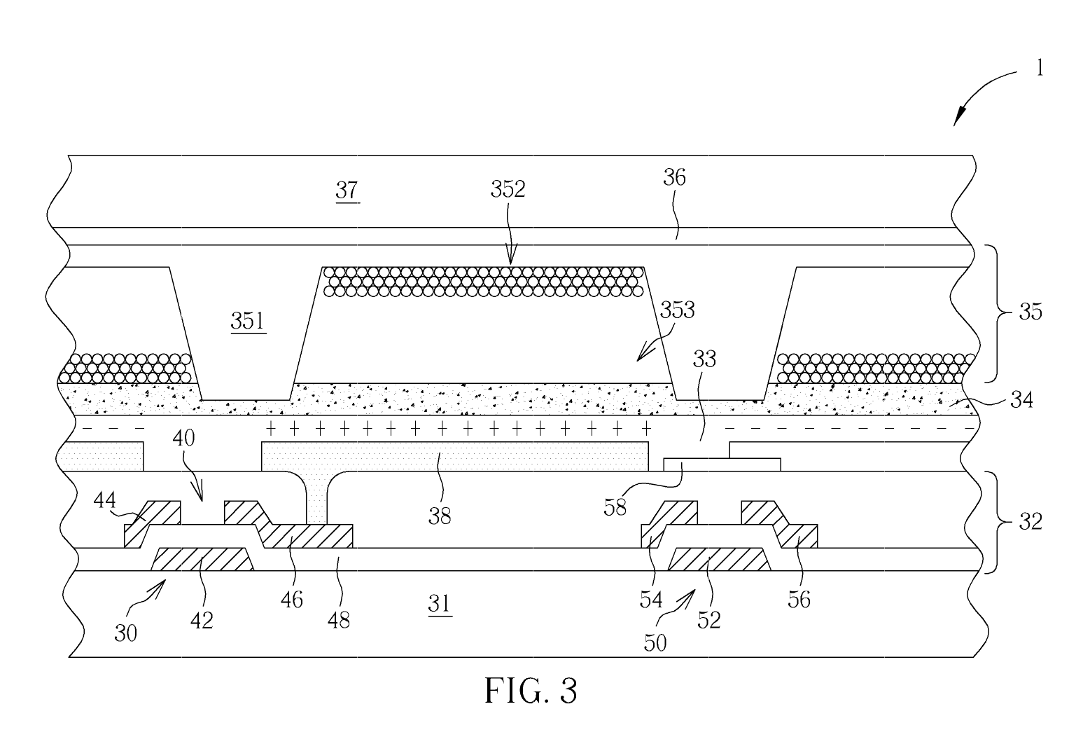

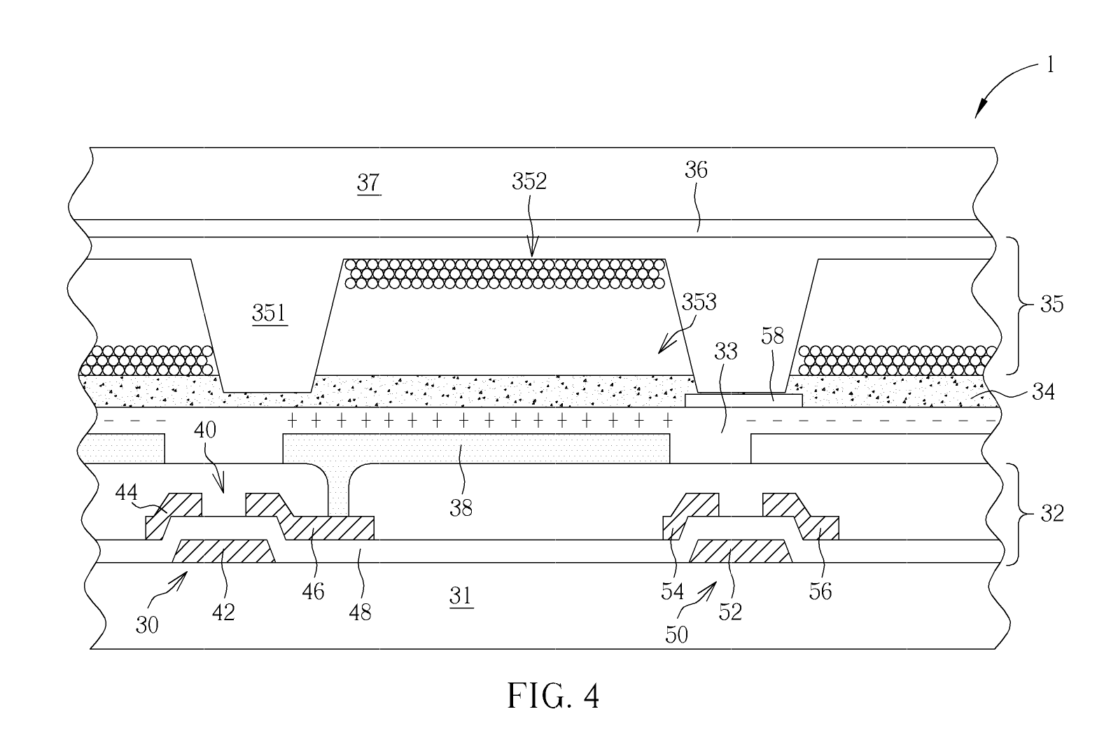

Please refer to FIG. 3 and FIG. 4. FIG. 3 and FIG. 4 are illustrations showing sectional structure of a second embodiment and a third embodiment of the electrophoretic display device 1 from the cutting line A-A in FIG. 1. For enhancing the sensitivity of the photosensitive transistor 50, it can be designed to sense lights with specific wavelength. For example, in the second embodiment of the electrophoretic display device 1, a filter 58 can be disposed on the photosensitive transistor 50, which is implemented as a blue or red plate as shown in FIG. 3, in the pixel electrode 38, or in the sealing layer 34 as shown in the third embodiment in FIG. 4. The filter 58 may include at least one from a group consisted of red, green, blue filters, black matrix, and any customized filter that is designed for filtering lights with specific wavelength. In another embodiment, the filter 58 can also extend to cover the overall surface of the display device 1. In still another embodiment, an additional filter can also be disposed in the electrophoretic layer 35, the transparent conductive layer 36, or the protective layer 37 that is capable of filtering lights with specific wavelength.

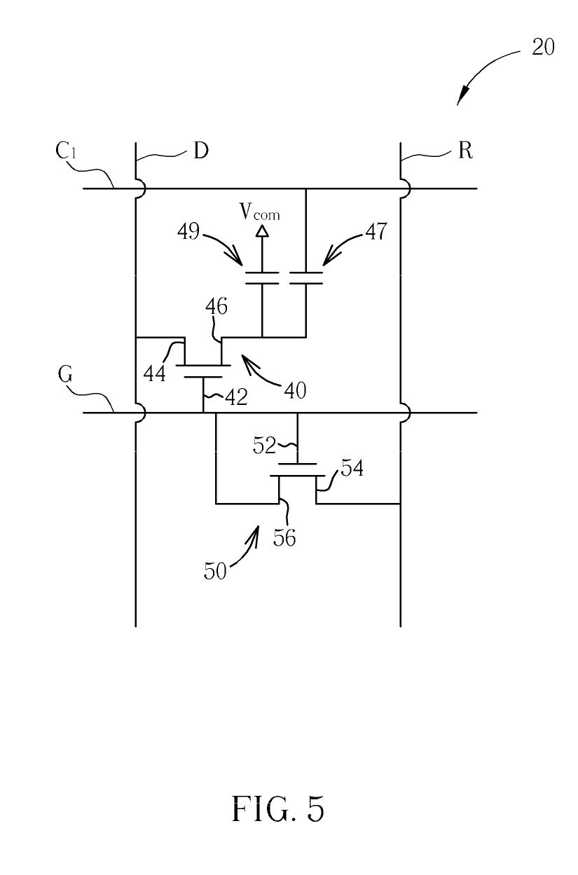

Please refer to FIG. 5. FIG. 5 is an illustration of a first embodiment of an equivalent circuit of a pixel structure 20 of the electrophoretic display device 1. The pixel structure 20 includes the thin film transistor 40 as mentioned, the photosensitive transistor 50, a storage capacitor 47, and a coupling capacitor 49. The gate 42 of the thin film transistor 40 is coupled to a gate line G and the source 44 is coupled to a data line D. The gate line G and the data line D are orthogonal to one another. The storage capacitor 47 is coupled between the drain 46 of the thin film transistor 40 and a CS line C₁, and the coupling capacitor 49 is coupled between the drain 46 and a common voltage V_{com}. In the embodiment of the invention, the coupling capacitor 49 is composed by the pixel electrode 38 and the electrophoretic layer 35, whereas the common voltage V_{com} is provided by the transparent conductive layer 36.

The gate 52 of the photosensitive transistor 50 is coupled to the gate line G, and the drain 56 is also coupled to the Gate line G and thus is short-circuited to the gate 52, which may advantageously prevent parasitic capacitance from accumulation therebetween. It should be noted that the CS line C₁ is orthogonal to the read-out line R. The source 54 of the photosensitive transistor 50 is coupled to the read-out line R. When an optical signal is detected by the photosensitive transistor 50, the photosensitive transistor 50 generates a current provided to the IS FPC 90 via the read-out line R. In such way, the thin film transistor 40 controls the content to be display on the electrophoretic display device 1, while the photosensitive transistor 50 serves to detect an input optical signal provided from, for example, a light source such as a light pen or torch, or light variation caused by the shadow of an object such as a stylus or fingertip, and take the input optical signal as an input control signal. Thus, the electrophoretic display device 1 displays and also allows input control via photo sensing.

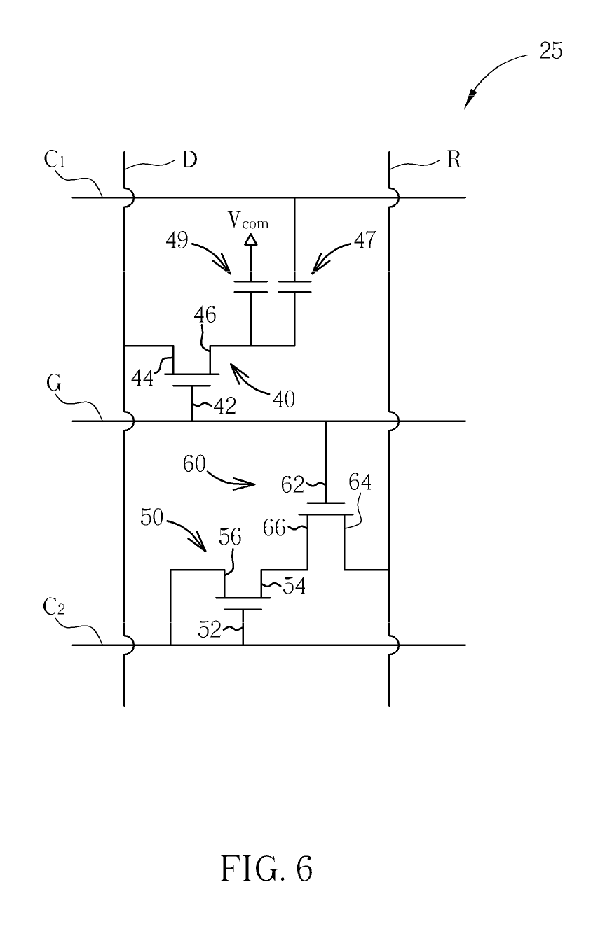

FIG. 6 is an illustration of a second embodiment of an equivalent circuit of a pixel structure 25 of the electrophoretic display device 1. The pixel structure 25 may be similar to the pixel structure 20 described in FIG. 5. Except, for example, the pixel structure 25 includes a switching transistor 60, also in the thin-film-transistor layer 32, that is used to drive the photosensitive transistor 50. While the storage capacitor 47 is coupled between the drain 46 of the thin film transistor 40 and a first CS line C₁, the gate 52 of the photosensitive transistor 50 is coupled to a second CS line C₂, and the drain 56 is also coupled to the second CS line C₂ and thus is short-circuited to the gate 52, which may advantageously prevent parasitic capacitance from accumulation therebetween. It should be noted that the first CS line C₁ and the second CS line C₂ are both orthogonal to the read-out line R. Additionally, the first CS line C₁ in the pixel structure 25 is also served as the second CS line C₂ in the adjacent pixel structure right above the pixel structure 25. The second CS line C₂ in the pixel structure 25 is also served as the first CS line C₁ in the adjacent pixel structure right below the pixel structure 25. The switching transistor 60 includes a gate 62 coupled to the gate line G, a source 64 coupled to the read-out line R, and a drain 66 coupled to the source 54 of the photosensitive transistor 50. When the photosensitive transistor 50 detects an input optical signal provided from, for example, a light source such as a light pen or torch, or light variation caused by the shadow of an object such as a stylus or fingertip, and the gate line G is selected, which turns on the switching transistor 60, the current generated by the photosensitive transistor 50 will be provided to the read-out line R. In the embodiment of FIG. 6, the thin film transistor 40 and the switching transistor 60 are coupled to the same gate line G.

The electrophoretic display device includes the photosensitive transistor in the thin-film-transistor layer that may be used to receive an optical signal as input control signal. The thin-film-transistor layer also includes the electrical switch element for driving the electrophoretic layer to display content. The switching transistor may also be included in the thin-film-transistor layer for selectively turning on the photosensitive transistor. By incorporating the photosensitive transistor and the switching transistor into the existing thin-film-transistor layer of the active matrix electrophoretic display device, optical sensing touch control is made applicable in the electrophoretic display device without compromising its advantageous light, flexible, thin features.

Those skilled in the art will readily observe that numerous modifications and alterations of the device and method may be made while retaining the teachings of the invention.

1. An electrophoretic display device, comprising:
a substrate;
a thin-film-transistor layer, comprising an electrical switch element disposed on the substrate and a photosensitive transistor disposed on the substrate, the photosensitive transistor capable of detecting an optical signal and converting the optical signal into a current signal;
a sealing layer disposed on the thin-film-transistor layer;
an electrophoretic layer disposed on the sealing layer;
a transparent conductive layer disposed on the electrophoretic layer; and
a protective layer disposed on the transparent conductive layer;
wherein the electrical switch element comprises a thin film transistor (TFT), a gate of the thin film transistor is coupled to a gate line, and a gate and a drain of the photosensitive transistor are coupled to the gate line.

2. The electrophoretic display device of claim 1, further comprising an adhesive layer covering on the thin-film-transistor layer.

3. The electrophoretic display device of claim 1, wherein a drain of the thin film transistor is coupled to a pixel electrode.

4. The electrophoretic display device of claim 3, comprising at least a pixel structure, the pixel structure comprising:
the thin film transistor of the electrical switch element;
a storage capacitor, coupled to the drain of the thin film transistor and a first capacitor storage (CS) line; and
the photosensitive transistor.

5-7. (canceled)

8. The electrophoretic display device of claim 4, wherein a source of the photosensitive transistor is coupled to a read-out line, and the gate line is orthogonal to the read-out line.

9. The electrophoretic display device of claim 4, wherein a source of the thin film transistor is coupled to a data line, and the gate line and the data line are orthogonal to one another.

10. The electrophoretic display device of claim 9, wherein the gate of the thin film transistor is disposed on the substrate, the thin film transistor further comprises a gate dielectric layer covering on the gate, and the source and the drain of the thin film transistor are disposed on the gate dielectric layer.

11. The electrophoretic display device of claim 4, wherein the pixel structure further comprises a coupling capacitor coupled to the drain of the thin film transistor and a common voltage, the coupling capacitor composed by the pixel electrode and the electrophoretic layer.

12. The electrophoretic display device of claim 1, wherein the electrophoretic display device is an active matrix electrophoretic display device.

13. The electrophoretic display device of claim 1, wherein the electrophoretic layer comprises a microcup structure having a plurality of microcups and dielectric fluid filled in each of the plurality of microcups.

14. The electrophoretic display device of claim 1, further comprising a filter disposed on the photosensitive transistor.

15. The electrophoretic display device of claim 14, wherein the filter includes at least one from a group consisted of red, green, blue filters, black matrix, and any customized filter that is designed for filtering lights with specific wavelength.

16. An electrophoretic display device, comprising:
a substrate;
a thin-film-transistor layer, comprising an electrical switch element disposed on the substrate, a photosensitive transistor disposed on the substrate, and a switching transistor for driving the photosensitive transistor, the photosensitive transistor capable of detecting an optical signal and converting the optical signal into a current signal;
a sealing layer disposed on the thin-film-transistor layer;
an electrophoretic layer disposed on the sealing layer;
a transparent conductive layer disposed on the electrophoretic layer; and
a protective layer disposed on the transparent conductive layer;
wherein the electrical switch element comprises a thin film transistor (TFT), both a gate of the thin film transistor and a gate of the switching transistor are coupled to a gate line, a gate and a drain of the photosensitive transistor are coupled to a capacitor storage (CS) line.

17. The electrophoretic display device of claim 16, wherein the switching transistor comprises a source coupled to a read-out line, the gate line and the read-out line being orthogonal to one another.

18. The electrophoretic display device of claim 17, wherein a source of the photosensitive transistor is coupled to a drain of the switching transistor.
